(19) United States
(12) Patent Application Publication
(10) Pub. No.: US 2025/0194123 A1
(43) Pub. Date: Jun. 12, 2025

(54) SCHOTTKY DIODE AND MANUFACTURING METHOD THEREOF

(71) Applicant: Enkris Semiconductor, Inc., Suzhou (CN)

(72) Inventor: Kai CHENG, Suzhou (CN)

(21) Appl. No.: 18/795,849

(22) Filed: Aug. 6, 2024

(30) Foreign Application Priority Data
Dec. 11, 2023 (CN) 202311696544.1

(51) Int. Cl. H01L 29/66; H01L 29/872

(52) U.S. Cl. CPC H10D 8/051; H10D 8/60

(57) ABSTRACT

A Schottky diode includes a substrate, a heterostructure, an anode, and a cathode. The heterostructure includes a planar heterojunction and multiple bar-shaped heterojunctions. The planar heterojunction is located on the substrate. The multiple bar-shaped heterojunctions are located on the surface of the planar heterojunction facing away from the substrate. Each two adjacent ones of the multiple bar-shaped heterojunctions are spaced apart. The anode is located at first ends of the multiple bar-shaped heterojunctions and on the surface of the planar heterojunction facing away from the substrate. The cathode is located at second ends of the multiple bar-shaped heterojunctions and on the surface of the planar heterojunction facing away from the substrate. This solution improves the 2DEG concentration and mobility at the heterojunction interface and improves the electrical performance of the component.

### CROSS-REFERENCE TO RELATED APPLICATION(S)

This application claims priority to Chinese Patent Application No. 202311696544.1 filed Dec. 11, 2023, the disclosure of which is incorporated herein by reference in its entirety.

### TECHNICAL FIELD

The present invention relates to the field of semiconductor technology, particularly a Schottky diode and a manufacturing method thereof.

### BACKGROUND

A GaN-based Schottky diode includes heterojunctions formed of materials such as GaN and AlGaN. High-concentration and high-mobility two-dimensional electron gas (2DEG) is formed at the heterojunction interface. GaN-based Schottky diodes are widely applied to high-frequency and high-speed components.

However, an existing GaN-based Schottky diode has insufficient 2DEG concentration and mobility at the heterojunction interface, seriously affecting the electrical performance of the GaN-based Schottky diode.

### SUMMARY

The present invention provides a Schottky diode and a manufacturing method thereof to improve the 2DEG concentration and mobility at the heterojunction interface and improve the electrical performance of the component.

According to an aspect of the present invention, a Schottky diode is provided. The Schottky diode includes a substrate, a heterostructure, an anode, and a cathode.

The heterostructure includes a planar heterojunction and a plurality of bar-shaped heterojunctions. The planar heterojunction is located on the substrate. The plurality of bar-shaped heterojunctions are located on the surface of the planar heterojunction facing away from the substrate. Each two adjacent bar-shaped heterojunctions are spaced apart.

The anode is located at first ends of the plurality of bar-shaped heterojunctions and on the surface of the planar heterojunction facing away from the substrate.

The cathode is located at second ends of the multiple bar-shaped heterojunctions and on the surface of the planar heterojunction facing away from the substrate. The plurality of bar-shaped heterojunctions extend from the first ends of the plurality of bar-shaped heterojunctions to the second ends of the plurality of bar-shaped heterojunctions.

According to another aspect of the present invention, a manufacturing method of a Schottky diode is provided. The method includes forming a planar heterojunction on the substrate; forming a plurality of bar-shaped heterojunctions on the surface of the planar heterojunction facing away from the substrate, where each two adjacent bar-shaped heterojunctions are spaced apart, and the planar heterojunction and the plurality of bar-shaped heterojunctions constitute a heterostructure; and forming an anode and a cathode on the surface of the planar heterojunction facing away from the substrate, where the anode is located at first ends of the plurality of bar-shaped heterojunctions, the cathode is located at second ends of the plurality of bar-shaped heterojunctions, and the plurality of bar-shaped heterojunctions extend from the first ends of the plurality of bar-shaped heterojunctions to the second ends of the plurality of bar-shaped heterojunctions.

### BRIEF DESCRIPTION OF DRAWINGS

FIG. 1 is a diagram illustrating the structure of a Schottky diode according to an embodiment of the present invention.

FIG. 2 is a diagram illustrating the structure of another Schottky diode according to an embodiment of the present invention.

FIG. 3 is a diagram illustrating the structure of another Schottky diode according to an embodiment of the present invention.

FIG. 4 is a diagram illustrating the structure of another Schottky diode according to an embodiment of the present invention.

FIG. 5 is a section view of FIG. 2 along direction A1-A2.

FIG. 6 is a top view of FIG. 2.

FIG. 7 is a diagram illustrating the structure of another Schottky diode according to an embodiment of the present invention.

FIG. 8 is a section view of FIG. 7 along direction B1-B2.

FIG. 9 is a section view of FIG. 7 along direction C1-C2.

FIG. 10 is a diagram illustrating the structure of another Schottky diode according to an embodiment of the present invention.

FIG. 11 is a diagram illustrating the structure of another Schottky diode according to an embodiment of the present invention.

FIG. 12 is a flowchart of a manufacturing method of a Schottky diode according to an embodiment of the present invention.

FIGS. 13 to 15 are diagrams illustrating structures corresponding to steps of FIG. 12.

FIG. 16 is a flowchart included in S130 of FIG. 12.

FIGS. 17 and 18 are diagrams illustrating structures corresponding to steps of FIG. 16.

FIG. 19 is another flowchart included in S130 of FIG. 12.

FIG. 20 is a diagram illustrating a structure corresponding to S1304 of FIG. 19.

FIG. 21 is a flowchart included after S130 of FIG. 12.

FIGS. 22 and 23 are diagrams illustrating structures corresponding to steps of FIG. 21.

FIG. 24 is another flowchart included after S130 of FIG. 12.

FIGS. 25 and 26 are diagrams illustrating structures corresponding to steps of FIG. 24.

FIGS. 27 and 28 are diagrams illustrating other types of structures corresponding to steps of FIG. 24.

### DETAILED DESCRIPTION

For a better understanding of solutions of the present invention by those skilled in the art, solutions in embodiments of the present invention are described clearly and completely hereinafter in conjunction with the drawings in embodiments of the present invention. Apparently, the embodiments described hereinafter are part, not all, of embodiments of the present invention. It is to be noted that terms such as “first” and “second” in the description, claims and the drawings of the present invention are used to distinguish between similar objects and are not necessarily used to describe a particular order or sequence.

To improve the 2DEG concentration and mobility at a heterojunction interface, reduce a reverse leakage, and improve the electrical performance of a component, this embodiment of the present invention provides the following solutions:

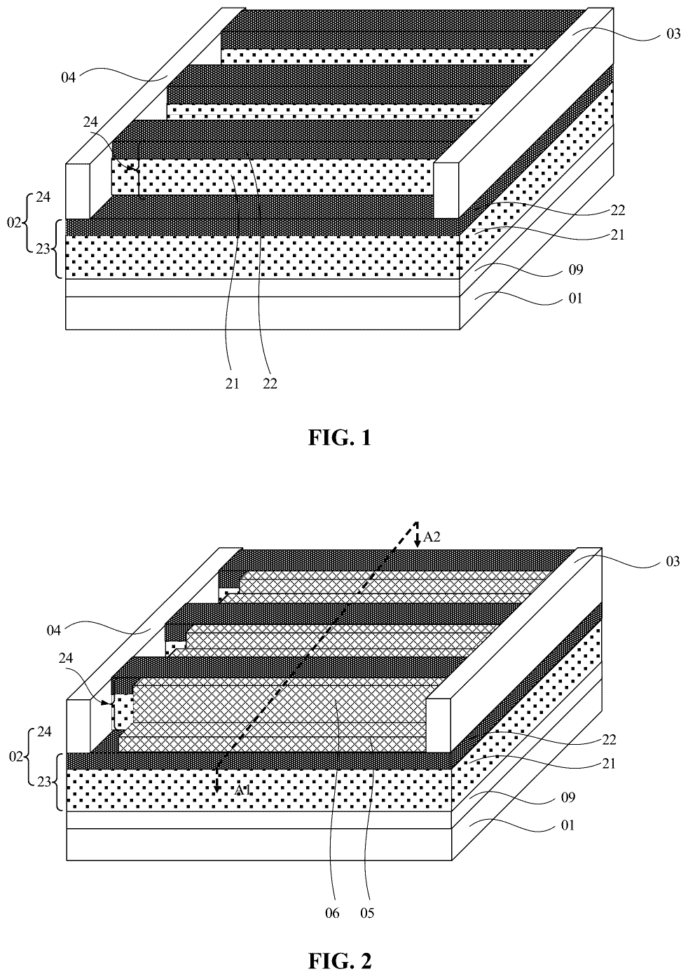

FIG. 1 is a diagram illustrating the structure of a Schottky diode according to an embodiment of the present invention. The Schottky diode includes a substrate 01, a heterostructure 02, an anode 03, and a cathode 04. The heterostructure 02 includes a planar heterojunction 23 and multiple bar-shaped heterojunctions 24. The planar heterojunction 23 is located on the substrate 01. The multiple bar-shaped heterojunctions 24 are located on the surface of the planar heterojunction 23 facing away from the substrate 01. Each two adjacent bar-shaped heterojunctions 24 are spaced apart. The anode 03 is located at first ends of the multiple bar-shaped heterojunctions 24 and on the surface of the planar heterojunction 23 facing away from the substrate 01. The cathode 04 is located at second ends of the multiple bar-shaped heterojunctions 24 and on the surface of the planar heterojunction 23 facing away from the substrate 01. The multiple bar-shaped heterojunctions 24 extend from the first ends of the multiple bar-shaped heterojunctions 24 to the second ends of the multiple bar-shaped heterojunctions 24.

Specifically, each bar-shaped heterojunction 24 includes a channel layer 21 and a barrier layer 22. High-concentration and high-mobility 2DEG is formed near the interface between the channel layer 21 and the barrier layer 22.

Optionally, the heterostructure 02 includes one of an AlGaN/GaN heterostructure, an AlScN/GaN heterostructure, or an AlN/GaN heterostructure. The channel layer 21 includes GaN. The barrier layer 22 includes one of AlGaN, AlScN, or AlN.

Optionally, the multiple bar-shaped heterojunctions 24 share the cathode 04 and the anode 03, simplifying the structure of the cathode 04 and the structure of the anode 03.

Optionally, the Schottky diode also includes a buffer layer 09 located between the substrate 01 and the heterostructure 02. The buffer layer 09 is configured to alleviate the lattice mismatch between the substrate 01 and the heterostructure 02 to improve the film forming quality of the heterostructure 02.

According to the solution of this embodiment of the present invention, the heterostructure 02 includes a planar heterojunction 23 and multiple bar-shaped heterojunctions 24. 2DEG is formed near the interface between the channel layer 21 and the barrier layer 22, and the multiple bar-shaped heterojunctions are located between the anode and the cathode to form current channels connected in parallel, thereby improving the 2DEG concentration in the Schottky diode, making a high 2DEG concentration alternate with a low 2DEG concentration, and thus improving the 2DEG mobility. Additionally, 2DEG conductive channels at the interface between the planar heterojunction 23 and the multiple bar-shaped heterojunctions 24 of the heterostructure 02 are connected in parallel, limiting motion within the conductive channels connected in parallel, widening the cross-conductance stability period, and thereby improving the cross-conductance stability and the linearity of the component. In summary, this solution improves the 2DEG concentration and mobility at the heterojunction interface and improves the electrical performance of the component.

Optionally, the anode may be located at the first end of the planar heterojunction, and the cathode may be located at the second end of the planar heterojunction.

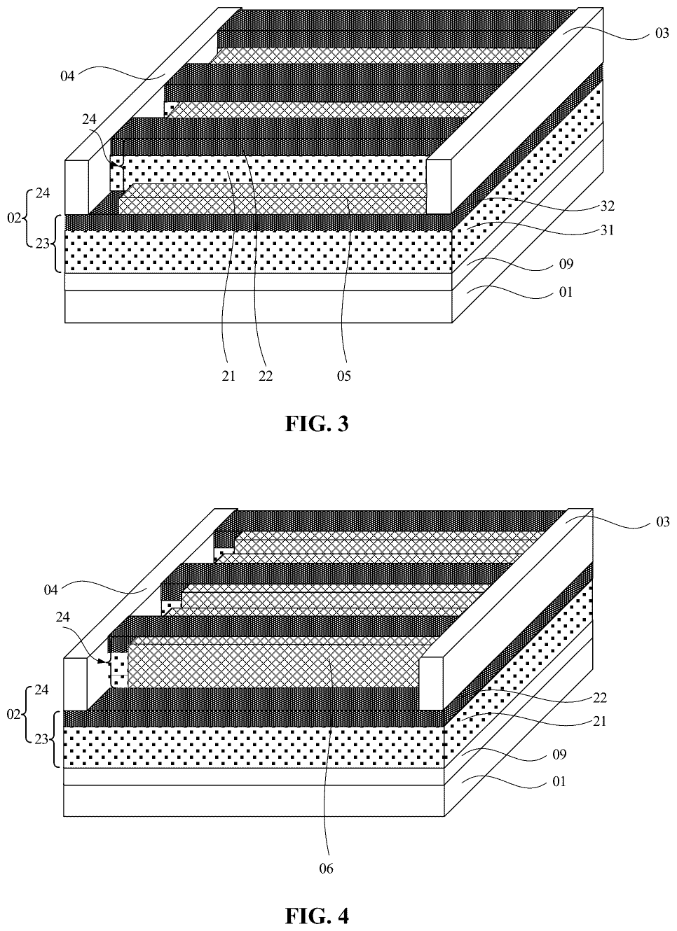

Optionally, based on the preceding solution, FIG. 2 is a diagram illustrating the structure of another Schottky diode according to an embodiment of the present invention, FIG. 3 is a diagram illustrating the structure of another Schottky diode according to an embodiment of the present invention, and FIG. 4 is a diagram illustrating the structure of another Schottky diode according to an embodiment of the present invention. As shown in FIGS. 2 to 4, the Schottky diode also includes a first p-GaN layer 05 and/or a second p-GaN layer 06. The first p-GaN layer 05 is located between two adjacent bar-shaped heterojunctions 24. The first p-GaN layer 05 is located between two adjacent bar-shaped heterojunctions 24 and on the surface of the planar heterojunction 23 facing away from the substrate 01. The second p-GaN layer 06 is located on a lateral face of a bar-shaped heterojunction.

FIG. 2 shows a solution in which the Schottky diode includes a first p-GaN layer 05 and a second p-GaN layer 06. FIG. 3 shows a solution in which the Schottky diode includes a first p-GaN layer 05 located at the bottom of a recess formed between two bar-shaped heterojunctions 24. Optionally, the first p-GaN layer 05 of FIG. 3 is manufactured in a selective epitaxy process.

FIG. 4 shows a solution in which the Schottky diode includes a second p-GaN layer 06 located on a lateral face of a recess formed between two bar-shaped heterojunctions 24. Optionally, the second p-GaN layer 06 of FIG. 4 is manufactured in a selective epitaxy process.

Optionally, as shown in FIG. 2, the Schottky diode includes a first p-GaN layer 05 and a second p-GaN layer 06 connected to the first p-GaN layer 05.

Specifically, the first p-GaN layer 05 is located between two adjacent bar-shaped heterojunctions 24 and on the surface of the planar heterojunction 23 facing away from the substrate 01, depleting 2DEG below the first p-GaN layer 05 in the planar heterojunction 23, making redistributed the electric field of the planar heterojunction 23, preventing an avalanche breakdown, improving the actual breakdown voltage of the Schottky barrier diode, and reducing a reverse leakage current.

The second p-GaN layer 06 is located on a lateral face of a bar-shaped heterojunction 24. When the Schottky diode is in the off state, a PN junction depletion region is formed between a second p-GaN layer 06, a second p-GaN layer 06, and an adjacent bar-shaped heterojunction 24. A relatively large depletion region can be acquired at a relatively low voltage. The depletion region can turn off a conductive channel of the bar-shaped heterojunction to form a large high-resistance region, thereby effectively reducing a reverse leakage.

Optionally, based on the previous solution, as shown in FIGS. 2 and 3, the first p-GaN layer 05 is in no contact with the cathode 04 and is in contact with the anode 03.

Optionally, based on the previous solution, as shown in FIGS. 2 and 4, the second p-GaN layer 06 is in no contact with the cathode 04 and is in contact with the anode 03.

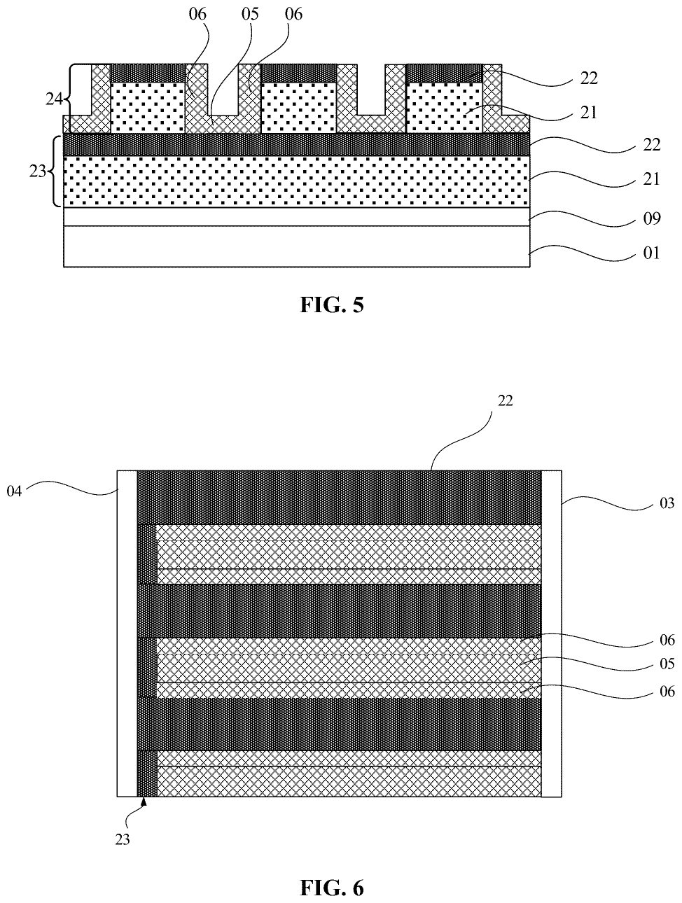

FIG. 5 is a section view of FIG. 2 along direction A1-A2. FIG. 6 is a top view of FIG. 2. Optionally, based on the previous solution, as shown in FIGS. 5 and 6, the Schottky diode includes a first p-GaN layer 05 and a second p-GaN layer 06. Second p-GaN layers 06 and a first p-GaN layer 05 that are located between two bar-shaped heterojunctions 24 constitute a U-shaped structure. A first p-GaN layer 05 and a second p-GaN layer 06 that are located at an edge of the planar heterojunction 23 constitute an L-shaped structure.

Specifically, the Schottky diode includes a first p-GaN layer 05 and a second p-GaN layer 06. In a direction in which the multiple bar-shaped heterojunctions 24 are arranged, a first p-GaN layer 05 completely covers the planar heterojunction 23 between two bar-shaped heterojunctions 24, depleting 2DEG below the first p-GaN layer 05 in the planar heterojunction 23, making redistributed the electric field of the planar heterojunction 23 between two bar-shaped heterojunctions 24, preventing an avalanche breakdown during a reverse offset, improving the actual breakdown voltage of the Schottky barrier diode, and reducing a reverse leakage current. It is to be noted that neither the first p-GaN layer 05 nor the second p-GaN layer 06 contacts the cathode 04 in a direction perpendicular to the direction in which the multiple bar-shaped heterojunctions 24 are arranged.

A first p-GaN layer 05 and a second p-GaN layer 06 that are located at an edge of the planar heterojunction 23 constitute an L-shaped structure. In a direction in which the multiple bar-shaped heterojunctions 24 are arranged, a first p-GaN layer 05 completely covers an edge of the planar heterojunction 23, depleting 2DEG below the first p-GaN layer 05, making redistributed the electric field at the edge of the planar heterojunction 23, preventing an avalanche breakdown, improving the actual breakdown voltage of the Schottky barrier diode, and reducing a reverse leakage current. It is to be noted that neither the first p-GaN layer 05 nor the second p-GaN layer 06 contacts the cathode 04 in a direction perpendicular to the direction in which the multiple bar-shaped heterojunctions 24 are arranged.

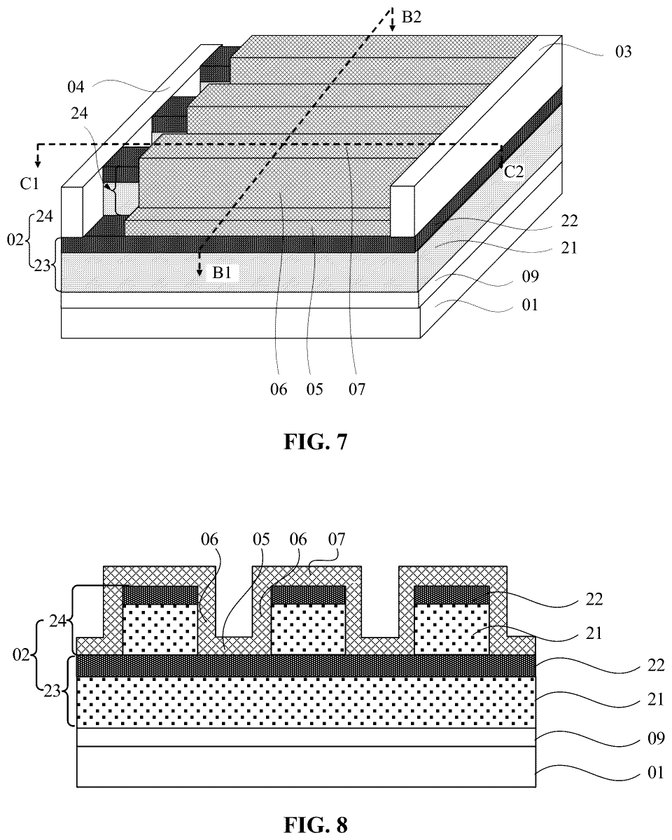

FIG. 7 is a diagram illustrating the structure of another Schottky diode according to an embodiment of the present invention. FIG. 8 is a section view of FIG. 7 along direction B1-B2. Optionally, based on the previous solution, as shown in FIGS. 7 and 8, the Schottky diode also includes a third p-GaN layer 07 located on the surface of a bar-shaped heterojunction 24 facing away from the planar heterojunction 23.

Specifically, a third p-GaN layer 07 can deplete 2DEG in the bar-shaped heterojunction 24 below the third p-GaN layer 07, improving redistribution of the electric field of the planar heterojunction 23 below the bar-shaped heterojunction 24, preventing an avalanche breakdown, improving the actual breakdown voltage of the Schottky barrier diode, and reducing a reverse leakage current.

Optionally, as shown in FIGS. 7 and 8, a third p-GaN layer 07 is also located on the surface of a second p-GaN layer 06 facing away from a first p-GaN layer 05 so that a structure in which the second p-GaN layer 06 and the third p-GaN layer 07 are connected to each other is formed.

FIG. 9 is a section view of FIG. 7 along direction C1-C2. Optionally, based on the previous solution, as shown in FIG. 9, the Schottky diode also includes a fourth p-GaN layer 08 located between the anode 03 and a bar-shaped heterojunction 24.

Specifically, the fourth p-GaN layer 08 is located on a lateral face of a bar-shaped heterojunction 24 and between the anode 03 and the bar-shaped heterojunction 24. When the Schottky diode is in the off state, a PN junction depletion region is formed near the fourth p-GaN layer 08. A relatively large depletion region can be acquired at a relatively low voltage. The depletion region can turn off a conductive channel to form a large high-resistance region, thereby effectively reducing a reverse leakage.

Optionally, as shown in FIG. 9, a fourth p-GaN layer 08 is connected to a third p-GaN layer 07. Optionally, a fourth p-GaN layer 08 is connected to a second p-GaN layer 06.

Optionally, between two adjacent bar-shaped heterojunctions 24, the surface of the planar heterojunction 23 facing away from the substrate 01 has a (1-100) crystal face or a (11-20) crystal face. Specifically, between two adjacent bar-shaped heterojunctions 24, a first p-GaN layer 05 and a bar-shaped heterojunction 24 are manufactured on the surface of the planar heterojunction 23 facing away from the substrate 01 in an epitaxy process. The (1-100) crystal face or the (11-20) crystal face is a non-polar plane, reducing an unstable chemical bond formed by a combination with an oxygen atom in the environment or substrate, reducing the interface state density, and thereby improving the component characteristics of the Schottky diode.

Optionally, the lateral face of the bar-shaped heterojunction 24 is a semi-polar plane or a non-polar plane. Specifically, the semi-polar plane and the non-polar plane can reduce an unstable chemical bond formed by a combination with an oxygen atom in the environment or substrate, thereby improving the component characteristics.

Optionally, the Schottky diode includes a first p-GaN layer 05 and a second p-GaN layer 06. The thickness of the first p-GaN layer 05 in the direction from the substrate 01 to the heterostructure 02 is greater than the thickness of the second p-GaN layer 06 in the direction parallel to the plane where the substrate 01 is located.

Optionally, the Schottky diode includes a first p-GaN layer 05 and a second p-GaN layer 06. The concentration of p-type doping elements in the first p-GaN layer 05 is higher than the concentration of p-type doping elements in the second p-GaN layer 06.

Specifically, the surface of the planar heterojunction 23 facing away from the substrate 01 has a (0001) crystal face that is a polar plane. Compared with a polar plane, a half-polar plane or a non-polar plane has a slower epitaxial rate. Therefore, the thickness of the second p-GaN layer 06 located on the lateral face of the bar-shaped heterojunction 24 is smaller. Additionally, the concentration of p-type doping elements in the second p-GaN layer 06 is lower. In this case, a PN junction depletion region is formed between a second p-GaN layer 06, a second p-GaN layer 06, and an adjacent bar-shaped heterojunction 24. The depletion region can turn off a conductive channel of the bar-shaped heterojunction, thereby effectively reducing a reverse leakage.

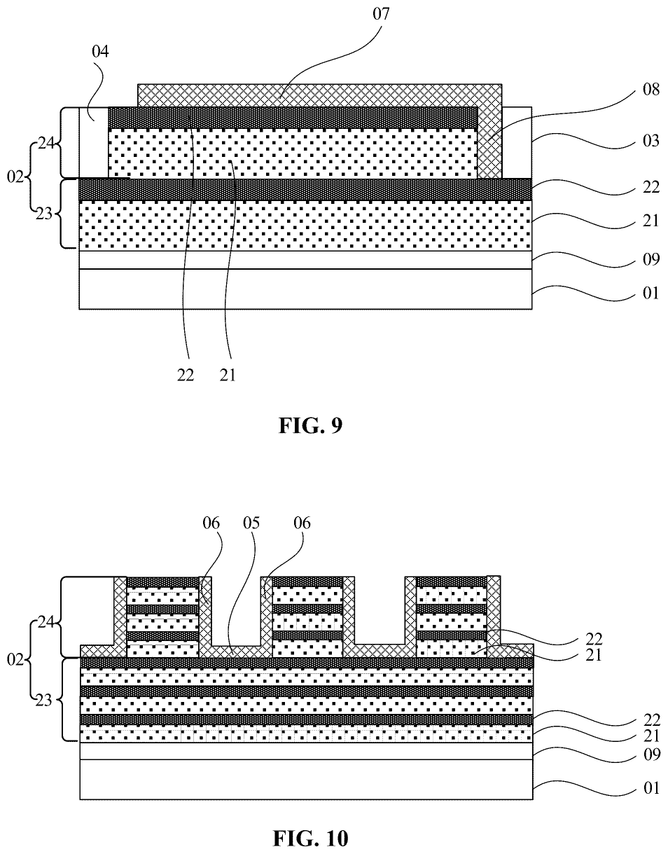

FIG. 10 is a diagram illustrating the structure of another Schottky diode according to an embodiment of the present invention. Optionally, based on the previous solution, as shown in FIG. 10, the planar heterojunction 23 includes a plurality of channel layers 21 and a plurality of barrier layers 22 that alternate with each other.

Optionally, the plurality of channel layers 21 and the plurality of barrier layers 22 that alternate with each other can increase the 2DEG concentration in a channel at the heterojunction interface of the planar heterojunction 23 to improve the electrical performance of the component.

Optionally, on the basis of the previous solution, as shown in FIG. 10, each bar-shaped heterojunction includes a plurality of channel layers 21 and a plurality of barrier layers 22 that alternate with each other. Optionally, as shown in FIG. 10, a second p-GaN layer 06 covers an entire lateral face of a bar-shaped heterojunction 24 that has channel layers 21 and barrier layers 22 that form multiple pairs.

Optionally, a bar-shaped heterojunction 24 that has channel layers 21 and barrier layers 22 that alternate with each other has a higher 2DEG concentration in a channel at the heterojunction interface of the bar-shaped heterojunction 24, thereby improving the electrical performance of the component.

It is to be noted that the planar heterojunction 23 and the bar-shaped heterojunction 24 may include the same number of pairs (each pair consists of one channel layer and one barrier layer). As shown in FIG. 10, the planar heterojunction 23 includes three channel layers 21 and three barrier layers 22 that alternate with each other. Optionally, the planar heterojunction 23 and the bar-shaped heterojunction 24 may include different numbers of pairs (each pair consists of one channel layer and one barrier layer).

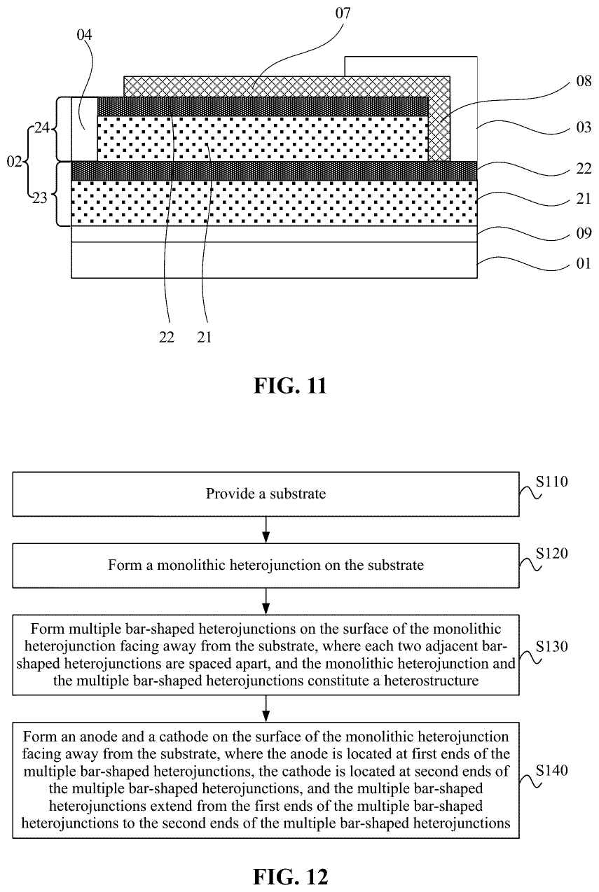

FIG. 11 is a diagram illustrating the structure of another Schottky diode according to an embodiment of the present invention. Optionally, based on the previous solution, as shown in FIG. 11, the anode 03 is a field plate structure that extends from the first ends of the multiple bar-shaped heterojunctions 24 to surfaces of the multiple bar-shaped heterojunctions 24 facing away from the planar heterojunction 23.

Optionally, the anode 03 is a field plate structure, and a partial anode 03 on the third p-GaN layer 07 can reduce the turn-on voltage of the Schottky diode, ensure a better reverse conduction capability, prevent an avalanche breakdown during reverse conduction, and improve the reliability of the Schottky diode.

It is to be noted that, as shown in FIG. 11, the anode 03 covers the fourth p-GaN layer 08 and part of the third p-GaN layer 07.

Optionally, the anode 03 also covers the first end of the planar heterojunction 23, and the cathode 04 also covers the second end of the planar heterojunction 23, facilitating control of turning on and off of the Schottky diode. The first end of the planar heterojunction 23 and the first ends of the multiple bar-shaped heterojunctions 24 are located on the same side of the heterostructure 02. The second end of the planar heterojunction 23 and the second ends of the multiple bar-shaped heterojunctions 24 are located on the same side of the heterostructure 02.

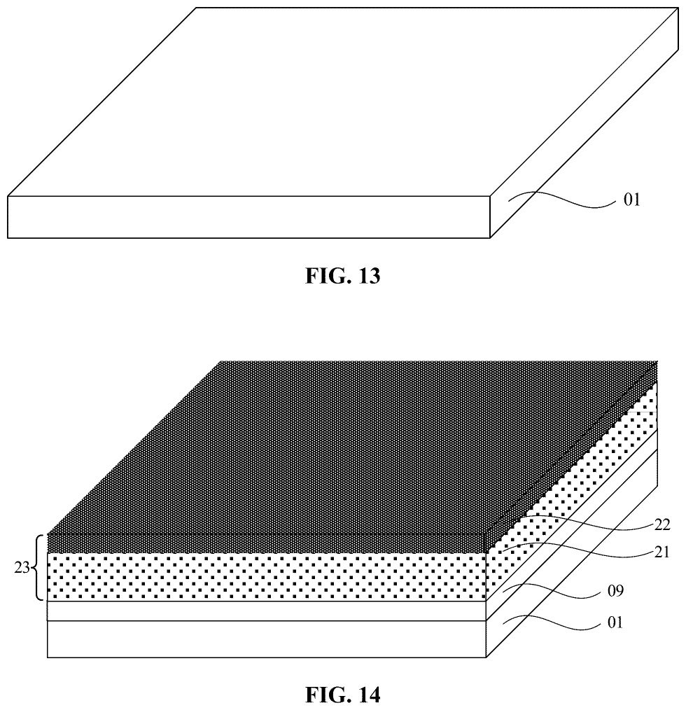

An embodiment of the present invention provides a manufacturing method of a Schottky diode. FIG. 12 is a flowchart of a manufacturing method of a Schottky diode according to an embodiment of the present invention. FIGS. 13 to 15 are diagrams illustrating structures corresponding to steps of FIG. 12. As shown in FIG. 12, the manufacturing method of a Schottky diode includes S110 to S140.

In S110, as shown in FIG. 13, a substrate 01 is provided. The substrate 01 may be formed of sapphire, silicon carbide, silicon, diamond, or gallium nitride.

In S120, as shown in FIG. 14, a planar heterojunction 23 is formed on the substrate 01. A buffer layer 09 is formed on the substrate 01, and then the planar heterojunction 23 is epitaxially formed on the surface of the buffer layer 09 facing away from the substrate 01. The buffer layer 09 is configured to alleviate the lattice mismatch between the substrate 01 and the heterostructure 02 to improve the film forming quality of the heterostructure 02.

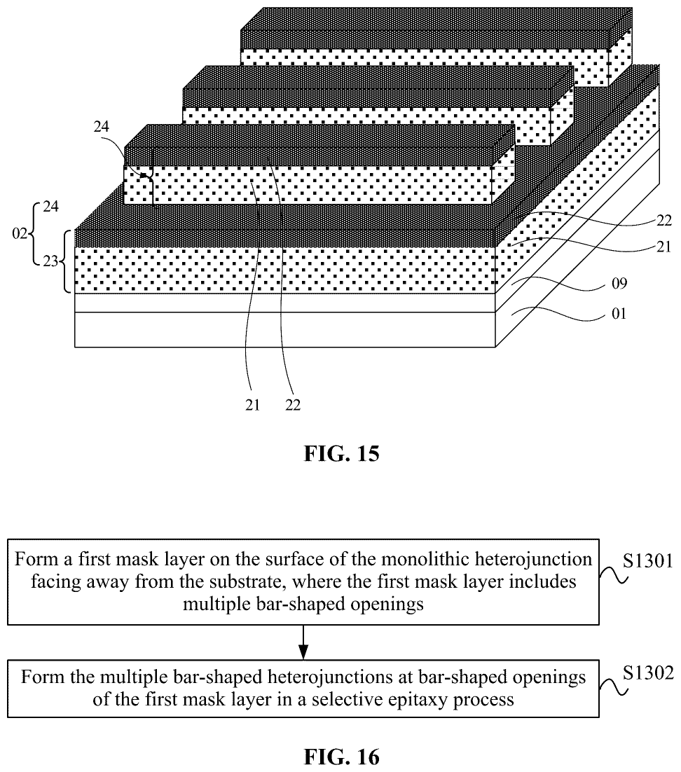

In S130, as shown in FIG. 15, multiple bar-shaped heterojunctions 24 are formed on the surface of the planar heterojunction 23 facing away from the substrate 01, where each two adjacent bar-shaped heterojunctions 24 are spaced apart, and the planar heterojunction 23 and the multiple bar-shaped heterojunctions 24 constitute a heterostructure 02. Optionally, multiple current channels connected in parallel are formed on the heterostructure 02, making a high 2DEG concentration alternate with a low 2DEG concentration.

In S140, as shown in FIG. 1, an anode 03 and a cathode 04 are formed on the surface of the planar heterojunction 23 facing away from the substrate 01, where the anode 03 is located at first ends of the multiple bar-shaped heterojunctions 24, the cathode 04 is located at second ends of the multiple bar-shaped heterojunctions 24, and the multiple bar-shaped heterojunctions 24 extend from the first ends of the multiple bar-shaped heterojunctions 24 to the second ends of the multiple bar-shaped heterojunctions 24. Optionally, the anode 03 and the cathode 04 may be formed by using a physical vapor deposition method or a chemical vapor deposition method. The anode 03 may be formed of a metal such as Ti/Al/Ni/Au or Ni/Au. The cathode 04 may be formed of a metal such as Ti/Al/Ni/Au, Ni/Au, Al, Zr, or Hf.

According to the solution of this embodiment of the present invention, the heterostructure 02 includes a planar heterojunction 23 and multiple bar-shaped heterojunctions 24. 2DEG is formed near the interface between the channel layer 21 and the barrier layer 22, and the multiple bar-shaped heterojunctions are located between the anode and the cathode to form current channels connected in parallel, thereby improving the 2DEG concentration in the Schottky diode, making a high 2DEG concentration alternate with a low 2DEG concentration, and thus improving the 2DEG mobility. Additionally, 2DEG conductive channels at the interface between the planar heterojunction 23 and the multiple bar-shaped heterojunctions 24 of the heterostructure 02 are connected in parallel, limiting motion within the conductive channels connected in parallel, widening the cross-conductance stability period, and thereby improving the cross-conductance stability and the linearity of the component. In summary, this solution improves the 2DEG concentration and mobility at the heterojunction interface and improves the electrical performance of the component.

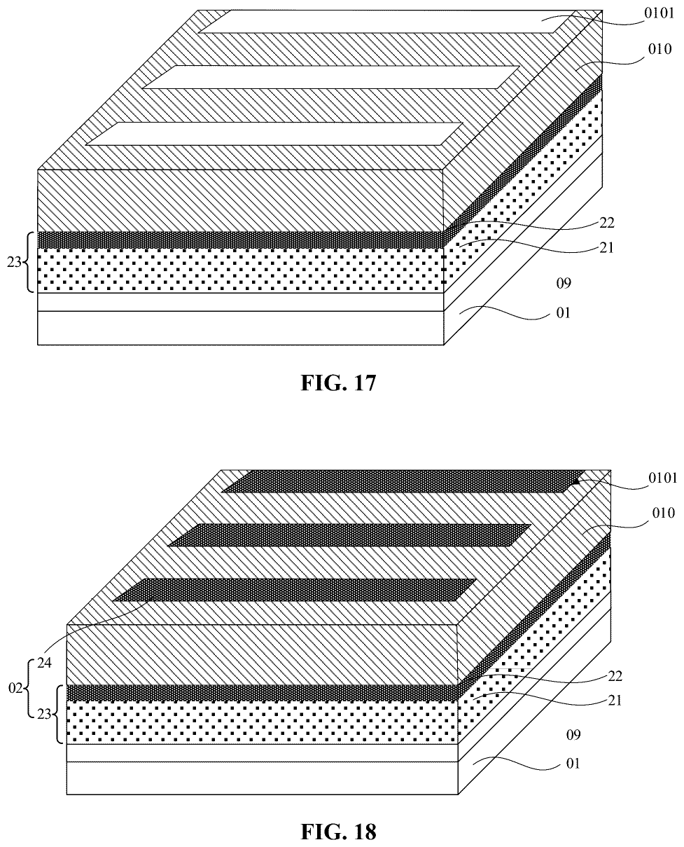

FIG. 16 is a flowchart included in S130 of FIG. 12. FIGS. 17 and 18 are diagrams illustrating structures corresponding to steps of FIG. 16. S130 (forming the multiple bar-shaped heterojunctions 24 on the surface of the planar heterojunction 23 facing away from the substrate 01) includes S1301 to S1303.

In S1301, as shown in FIG. 17, a first mask layer 010 is formed on the surface of the planar heterojunction 23 facing away from the substrate 01, where the first mask layer 010 includes multiple bar-shaped openings 0101. The first mask layer 010 may be one of a photoresist, an oxide of silicon, or a nitride of silicon.

In S1302, as shown in FIG. 18, the multiple bar-shaped heterojunctions 24 are formed at bar-shaped openings 0101 of the first mask layer 010 in a selective epitaxy process.

In S1303, as shown in FIG. 15, the first mask layer 010 is removed by using the etching technique so that multiple spaced bar-shaped heterojunctions 24 are formed.

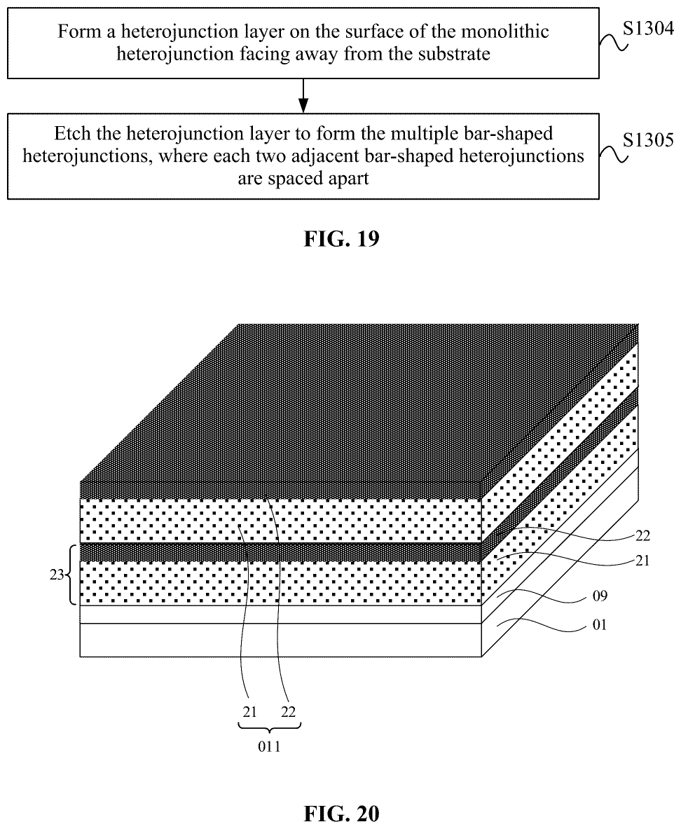

FIG. 19 is another flowchart included in S130 of FIG. 12. FIG. 20 is a diagram illustrating a structure corresponding to S1304 of FIG. 19. Alternatively, as shown in FIG. 19, forming the multiple bar-shaped heterojunctions 24 on the surface of the planar heterojunction 23 facing away from the substrate 01 includes S1304 and S1305.

In S1304, as shown in FIG. 20, a heterojunction layer 011 is formed on the surface of the planar heterojunction 23 facing away from the substrate 01 by using the epitaxy technique. Optionally, the channel layer 21 and the barrier layer 22 of the heterojunction layer 011 may be the same as the planar heterojunction 23 in terms of material and manufacturing process.

In S1305, as shown in FIG. 15, the heterojunction layer 011 is etched to form the multiple bar-shaped heterojunctions 24, where each two adjacent bar-shaped heterojunctions 24 are spaced apart.

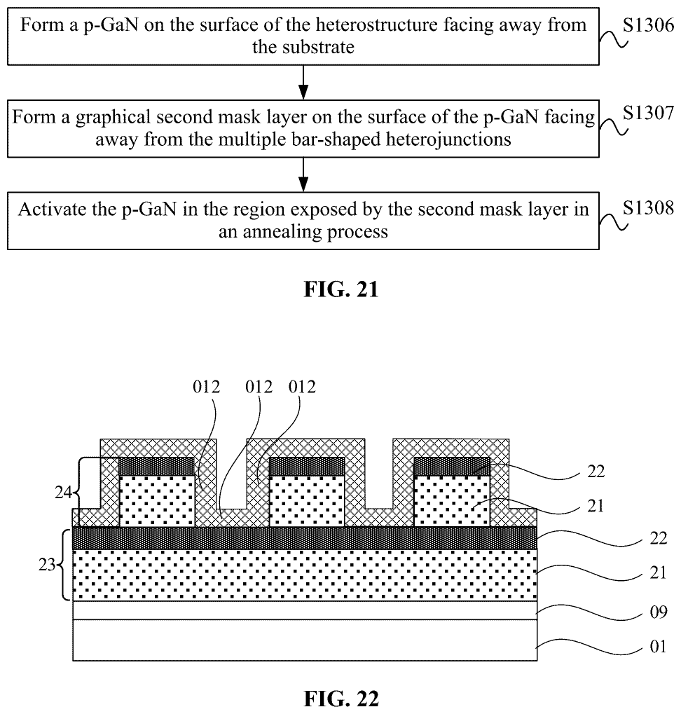

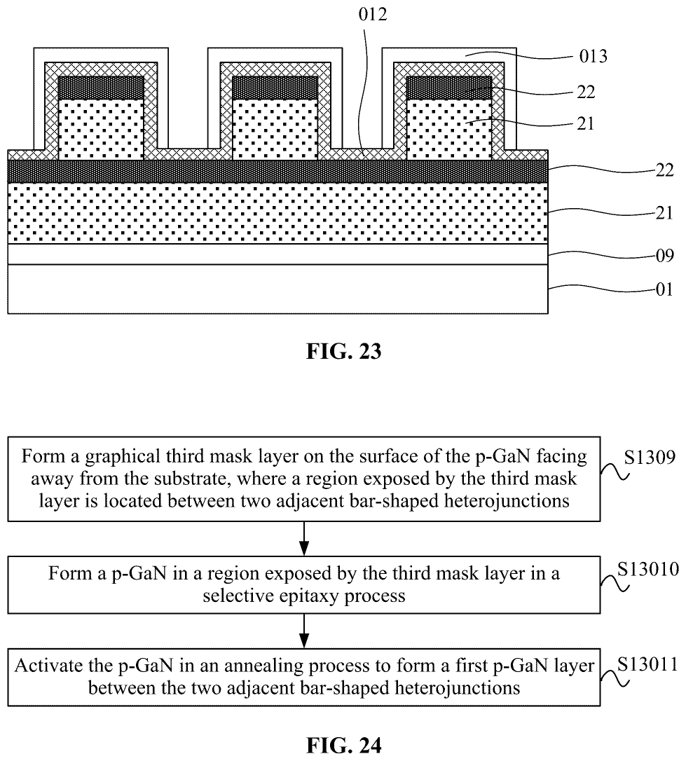

FIG. 21 is a flowchart included after S130 of FIG. 12. FIGS. 22 and 23 are diagrams illustrating structures corresponding to steps of FIG. 21. As shown in FIG. 21, after forming the multiple bar-shaped heterojunctions 24 on the surface of the planar heterojunction 23 facing away from the substrate 01, the method also includes S1306 to S1308.

In S1306, as shown in FIG. 22, a p-GaN 012 is formed on the surface of the heterostructure 02 facing away from the substrate 01. Optionally, p-type doping elements in the p-GaN 012 may be at least one of Mg, Zn, Ca, Sr, or Ba. It is to be noted that p-GaN 012 is a p-type doping semiconductor film that has not been activated by the annealing technique.

In S1307, as shown in FIG. 23, a graphical second mask layer 013 is formed on the surface of the p-GaN 012 facing away from the substrate 01, where a region exposed by the second mask layer 013 is located between two adjacent bar-shaped heterojunctions 24. Optionally, the second mask layer 013 covers the multiple bar-shaped heterojunctions 24. Optionally, the second mask layer 013 may first cover all of the heterostructure 02 and then form a graphical second mask layer 013 by being photoetched.

In S1308, the p-GaN 012 is activated in the region exposed by the second mask layer 013 in an annealing process to form a first p-GaN layer 05 between the two adjacent bar-shaped heterojunctions 24. Optionally, the second mask layer 013 plays the role of avoiding activation of the underlying p-GaN 012. Optionally, the second mask layer 013 is AlN or SiN. Optionally, the second mask layer 013 is removed later.

Optionally, between two adjacent bar-shaped heterojunctions 24, the crystal face of the region exposed by the second mask layer 013 is (1-100) or (11-20), conducive to the electric field strength at the included angle between the bar-shaped heterojunctions and the planar heterojunction in the subsequently manufactured component.

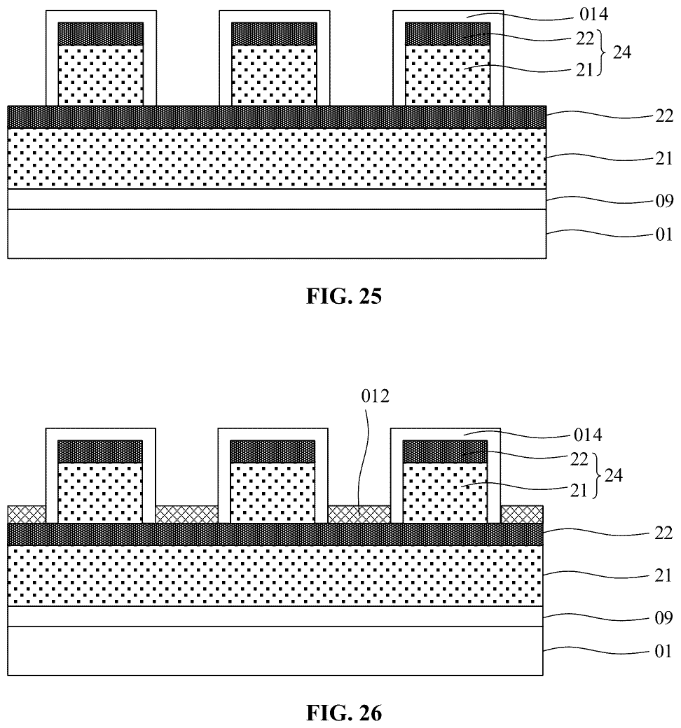

FIG. 24 is another flowchart included after S130 of FIG. 12. FIGS. 25 and 26 are diagrams illustrating structures corresponding to steps of FIG. 24. Alternatively, after forming the multiple bar-shaped heterojunctions 24 on the surface of the planar heterojunction 23 facing away from the substrate 01, the method also includes S1309 to S13011.

In S1309, as shown in FIG. 25, a graphical third mask layer 014 is formed on the surface of the p-GaN 012 facing away from the substrate 01, where a region exposed by the third mask layer 014 is located between two adjacent bar-shaped heterojunctions 24. Optionally, the third mask layer 014 covers the multiple bar-shaped heterojunctions 24. Optionally, the third mask layer 014 is formed of SiO or SiN.

In S13010, as shown in FIG. 26, a p-GaN 012 is formed in a region exposed by the third mask layer 014 in a selective epitaxy process.

In S13011, the p-GaN 012 is activated in an annealing process to form a first p-GaN layer 05 between the two adjacent bar-shaped heterojunctions 24. Optionally, the third mask layer 014 is removed later.

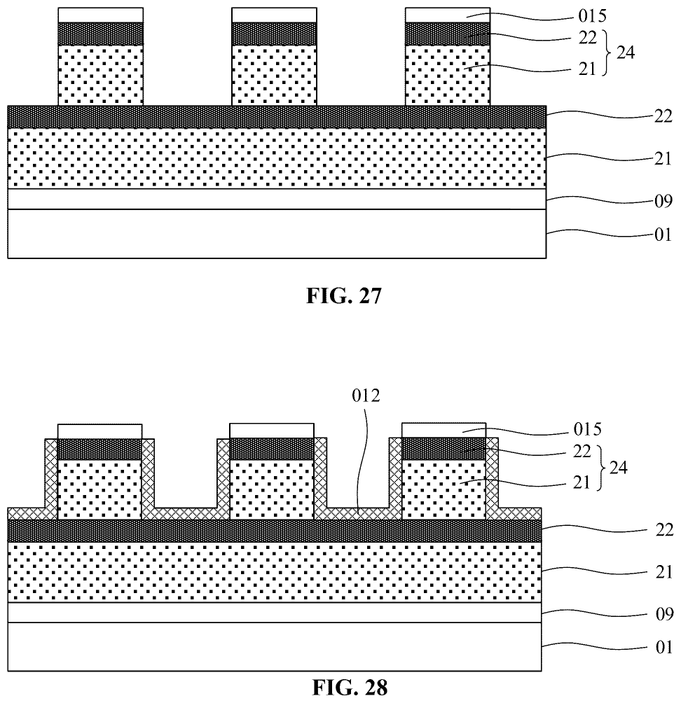

Optionally, FIGS. 27 and 28 are diagrams illustrating other types of structures corresponding to steps of FIG. 24. As shown in FIG. 27, a graphical fourth mask layer 015 is formed on the surfaces of the multiple bar-shaped heterojunctions 24 facing away from the substrate 01, where a region exposed by the fourth mask layer 015 is located between two adjacent bar-shaped heterojunctions 24 and lateral faces of the bar-shaped heterojunctions 24. As shown in FIG. 28, a p-GaN 012 is formed in a region exposed by the fourth mask layer 015 in a selective epitaxy process. As shown in FIG. 2, the p-GaN 012 is activated in an annealing process to form a first p-GaN layer 05 between two adjacent bar-shaped heterojunctions 24 and a second p-GaN layer 06 on lateral faces of the bar-shaped heterojunctions 24. Optionally, the fourth mask layer 015 is formed of SiO or SiN. Optionally, the fourth mask layer 015 is removed later.

It is to be noted that the GaN-based material epitaxial growth technique may be the metalorganic chemical vapor deposition (MOCVD) technique. When the MOCVD technique grows the GaN-based material, there are a large quantity of H atoms in the MOCVD growth environment, and acceptor dopants, such as Mg, in the GaN-based material are passivated by the large quantity of H atoms without generating holes. That is, doping ions of p-GaN 012 are not activated and cannot generate holes. As shown in FIG. 3, dopant ions of p-GaN 012 are activated in an annealing process. After p-type doping elements in the p-GaN 012 are activated, the H atoms may escape. For example, the Mg element may generate holes, consuming 2DEG at the heterostructure interface.

Particularly, when the Schottky diode also includes a third p-GaN layer 07 and a fourth p-GaN layer 08, p-GaN may be formed first. Then doping ions of p-GaN are activated in an annealing process to form the third p-GaN layer 07 and the fourth p-GaN layer 08. p-GaN forming the third p-GaN layer 07 and the fourth p-GaN layer 08 and p-GaN forming the first p-GaN layer 05 and the second p-GaN layer 06 may be prepared simultaneously.

As regards the Schottky diode and the manufacturing method thereof according to embodiments of the present application, in the Schottky diode, the heterostructure includes a planar heterojunction and a plurality of bar-shaped heterojunctions. 2DEG is formed near the interface between the channel layer and the barrier layer, and the plurality of bar-shaped heterojunctions are located between the anode and the cathode to form current channels connected in parallel, thereby improving the 2DEG concentration in the Schottky diode, making a high 2DEG concentration alternate with a low 2DEG concentration, and thus improving the 2DEG mobility. Additionally, 2DEG conductive channels at the interface between the planar heterojunction and the plurality of bar-shaped heterojunctions of the heterostructure are connected in parallel, limiting motion within the conductive channels connected in parallel, widening the cross-conductance stability period, and thereby improving the cross-conductance stability and the linearity of the component. In summary, this solution improves the 2DEG concentration and mobility at the heterojunction interface and improves the electrical performance of the component.

What is claimed is:

1. A Schottky diode, comprising:
a substrate;
a heterostructure, comprising a planar heterojunction and a plurality of bar-shaped heterojunctions, wherein the planar heterojunction is located on the substrate, the plurality of bar-shaped heterojunctions are located on a surface of the planar heterojunction facing away from the substrate, and each two adjacent ones of the plurality of bar-shaped heterojunctions are spaced apart;
an anode located at first ends of the plurality of bar-shaped heterojunctions and on the surface of the planar heterojunction facing away from the substrate; and
a cathode located at second ends of the plurality of bar-shaped heterojunctions and on the surface of the planar heterojunction facing away from the substrate, wherein the plurality of bar-shaped heterojunctions extend from the first ends of the plurality of bar-shaped heterojunctions to the second ends of the plurality of bar-shaped heterojunctions.

2. The Schottky diode of claim 1, wherein the heterostructure comprises one of an AlGaN/GaN heterostructure, an AlScN/GaN heterostructure, or an AlN/GaN heterostructure.

3. The Schottky diode of claim 1, further comprising a first p-GaN layer and a second p-GaN layer, wherein
the first p-GaN layer is located between two adjacent ones of the plurality of bar-shaped heterojunctions and on the surface of the planar heterojunction facing away from the substrate; and
the second p-GaN layer is located on a lateral face of a bar-shaped heterojunction of the plurality of bar-shaped heterojunctions.

4. The Schottky diode of claim 3, wherein between two adjacent ones of the plurality of bar-shaped heterojunctions, the surface of the planar heterojunction facing away from the substrate has a (1-100) crystal face or a (11-20) crystal face.

5. The Schottky diode of claim 3, wherein the lateral face of the bar-shaped heterojunction is a half-polar plane or a non-polar plane.

6. The Schottky diode of claim 5, comprising the first p-GaN layer and the second p-GaN layer, wherein a thickness of the first p-GaN layer in a direction from the substrate to the heterostructure is greater than a thickness of the second p-GaN layer in a direction parallel to a plane where the substrate is located.

7. The Schottky diode of claim 5, comprising the first p-GaN layer and the second p-GaN layer, wherein a concentration of p-type doping elements in the first p-GaN layer is higher than a concentration of p-type doping elements in the second p-GaN layer.

8. The Schottky diode of claim 3, comprising the first p-GaN layer and the second p-GaN layer, wherein
a first p-GaN layer and second p-GaN layers between two adjacent ones of the plurality of bar-shaped heterojunctions form a U-shaped structure.

9. The Schottky diode of claim 3, further comprising a third p-GaN layer located on a surface of the bar-shaped heterojunction facing away from the planar heterojunction.

10. The Schottky diode of claim 7, further comprising a fourth p-GaN layer located between the anode and the bar-shaped heterojunction.

11. The Schottky diode of claim 1, wherein the planar heterojunction comprises a plurality of channel layers and a plurality of barrier layers that alternate with each other; and/or
each of the plurality of bar-shaped heterojunctions comprises a plurality of channel layers and a plurality of barrier layers that alternate with each other.

12. The Schottky diode of claim 1, wherein the anode is a field plate structure that extends from the first ends of the plurality of bar-shaped heterojunctions to surfaces of the plurality of bar-shaped heterojunctions facing away from the planar heterojunction.

13. A manufacturing method of a Schottky diode, comprising:
providing a substrate;
forming a planar heterojunction on the substrate;
forming a plurality of bar-shaped heterojunctions on a surface of the planar heterojunction facing away from the substrate, wherein each two adjacent ones of the plurality of bar-shaped heterojunctions are spaced apart, and the planar heterojunction and the plurality of bar-shaped heterojunctions constitute a heterostructure; and
forming an anode and a cathode on the surface of the planar heterojunction facing away from the substrate, wherein the anode is located at first ends of the plurality of bar-shaped heterojunctions, the cathode is located at second ends of the plurality of bar-shaped heterojunctions, and the plurality of bar-shaped heterojunctions extend from the first ends of the plurality of bar-shaped heterojunctions to the second ends of the plurality of bar-shaped heterojunctions.

14. The manufacturing method of a Schottky diode of claim 13, wherein forming the plurality of bar-shaped heterojunctions on the surface of the planar heterojunction facing away from the substrate comprises:
forming a first mask layer on the surface of the planar heterojunction facing away from the substrate, wherein the first mask layer comprises a plurality of spaced bar-shaped openings;
forming the plurality of bar-shaped heterojunctions at bar-shaped openings in a selective epitaxy process; and
removing the first mask layer.

15. The manufacturing method of a Schottky diode of claim 13, wherein forming the plurality of bar-shaped heterojunctions on the surface of the planar heterojunction facing away from the substrate comprises:
forming a heterojunction layer on the surface of the planar heterojunction facing away from the substrate; and
etching the heterojunction layer to form the plurality of bar-shaped heterojunctions, wherein each two adjacent ones of the plurality of bar-shaped heterojunctions are spaced apart.

16. The manufacturing method of a Schottky diode of claim 13,
after forming the plurality of bar-shaped heterojunctions on the surface of the planar heterojunction facing away from the substrate, the method further comprising:
forming a p-GaN on a surface of the heterostructure facing away from the substrate;
forming a graphical second mask layer on a surface of the p-GaN facing away from the substrate, wherein a region exposed by the second mask layer is located between two adjacent ones of the plurality of bar-shaped heterojunctions; and
activating the p-GaN in the region exposed by the second mask layer in an annealing process to form a first p-GaN layer between the two adjacent ones of the plurality of bar-shaped heterojunctions.

17. The manufacturing method of a Schottky diode of claim 13, after forming the plurality of bar-shaped heterojunctions on the surface of the planar heterojunction facing away from the substrate, the method further comprising:
forming a graphical third mask layer on a surface of the heterostructure facing away from the substrate, wherein a region exposed by the third mask layer is located between two adjacent ones of the plurality of bar-shaped heterojunctions;
forming a p-GaN in a region exposed by the third mask layer in a selective epitaxy process; and
activating the p-GaN in an annealing process to form a first p-GaN layer between the two adjacent ones of the plurality of bar-shaped heterojunctions.

18. The Schottky diode of claim 1, further comprising a first p-GaN layer, wherein the first p-GaN layer is located between two adjacent ones of the plurality of bar-shaped heterojunctions and on the surface of the planar heterojunction facing away from the substrate.

19. The Schottky diode of claim 1, further comprising a second p-GaN layer, wherein the second p-GaN layer is located on a lateral face of a bar-shaped heterojunction of the plurality of bar-shaped heterojunctions.
